(19) United States
(12) Patent Application Publication
(10) Pub. No.: US 2026/0173977 A1
(43) Pub. Date: Jun. 18, 2026

(54) SEMICONDUCTOR DEVICE AND ELECTRONIC DEVICE

(71) Applicant: Renesas Electronics Corporation, Tokyo (JP)

(72) Inventors: Tetsuo FUKUSHI, Tokyo (JP); Masaki SANO, Tokyo (JP); Hiroshi KANNO, Tokyo (JP); Muneaki MATSUSHIGE, Tokyo (JP); Tristan LECOMTE, Tokyo (JP); Shuuichi KARIYAZAKI, Tokyo (JP)

(21) Appl. No.: 19/346,965

(22) Filed: Oct. 1, 2025

(30) Foreign Application Priority Data
Dec. 17, 2024 (JP) 2024-220788

(51) Int. Cl. H01L 23/498; H01L 23/00

(52) U.S. Cl. CPC H10W 90/701; H10W 70/65; H10W 70/685; H10W 90/401; H10W 90/724

(57) ABSTRACT

A plurality of external terminals arranged on a first bottom surface of an interposer substrate includes a plurality of power supply terminals capable of supplying a first power supply potential supplied from an external source to a first circuit. A second bottom surface includes a terminal arrangement region on which the plurality of external terminals are arranged, and a peripheral region surrounding the periphery of the terminal arrangement region. The terminal arrangement region includes a first region closest to a first edge of the interposer substrate and extending along the first edge. In the first region, only the plurality of power supply terminals among the plurality of external terminals are arranged so as to be adjacent to each other. Power consumption of the first circuit is the largest among the power consumption of each of the plurality of circuits of the semiconductor chip.

### CROSS-REFERENCE TO RELATED APPLICATIONS

The disclosure of Japanese Patent Application No. 2024-220788 filed on Dec. 17, 2024 including the specification, drawings and abstract is incorporated herein by reference in its entirety.

### BACKGROUND

The present invention relates to a semiconductor device and an electronic device.

There are disclosed techniques listed below.
[Patent Document 1] Japanese Unexamined Patent Application Publication No. 2015-154062
[Patent Document 2] International Patent Publication No. WO2016/046987

Patent Documents 1 and 2 disclose techniques regarding an electronic device in which a plurality of solder balls arranged on a bottom surface of a semiconductor device are each connected to a terminal on a mounting substrate.

### SUMMARY

Among a plurality of circuits of a semiconductor device, high functionality in a circuit such as a CPU (Central Processing Unit) requires the ability to process large amounts of data at high speeds, causing a significant increase in power consumption per unit time. Therefore, from the perspective of achieving the function to process large amounts of data at high speeds, it is necessary to develop a technique that can stably supply power to circuits with high power consumption.

Other problems and novel features will become apparent from the description of the present specification and attached drawings.

A semiconductor device according to one embodiment has a semiconductor chip, an interposer substrate, and a plurality of external terminals. The semiconductor chip has a plurality of circuits including a first circuit. The interposer substrate includes a first surface on which the semiconductor chip is mounted, and a second surface opposite to the first surface. The plurality of external terminals are arranged in alignment on the second surface of the interposer substrate. The plurality of external terminals include a plurality of first power supply terminals capable of supplying a first power supply potential supplied from an external source to the first circuit. The second surface includes a terminal arrangement region in which the plurality of external terminals are arranged, and a peripheral region surrounding a periphery of the terminal arrangement region. The terminal arrangement region includes a first region closest to a first edge of the interposer substrate and extending along the first edge. In the first region, only the plurality of first power supply terminals among the plurality of external terminals are arranged so as to be adjacent to each other. Power consumption of the first circuit is the largest among the power consumption of each of the plurality of circuits of the semiconductor chip.

An electronic device according to another embodiment includes the above-described semiconductor device and a wiring substrate. The wiring substrate includes a third surface and a fourth surface opposite to the third surface. The semiconductor device is mounted on the third surface of the wiring substate.

According to the embodiment described above, it is possible to improve performance of the semiconductor device or the electronic device including the semiconductor device.

### BRIEF DESCRIPTION OF THE DRAWINGS

FIG. 1 is a plan view of a top surface of an electronic device according to one embodiment.

FIG. 2 is a plan view of a bottom surface of the electronic device shown in FIG. 1.

FIG. 3 is a cross-sectional view along a line A-A of FIG. 1.

FIG. 4 is a plan view showing an example of a power plane and a ground plane among a plurality of conductor planes of a mounting substrate shown in FIG. 3.

FIG. 5 is a plan view of a bottom surface of a semiconductor device shown in FIG. 3.

FIG. 6 is an explanatory diagram showing an example of a layout of a plurality of circuits of the semiconductor chip shown in FIG. 3.

FIG. 7 is an explanatory diagram showing an example of an electrically connected state between the plurality of circuits shown in FIG. 6 and the plurality of external terminals shown in FIG. 5.

FIG. 8 is a plan view showing an example of relative positions of a power supply terminal, a reference potential terminal, and a differential signal terminal pair among the plurality of external terminals of the semiconductor device.

FIG. 9 is a plan view showing a semiconductor device which is a modification example relative to FIG. 8.

FIG. 10 is a plan view showing a semiconductor device which is another modification example relative to FIG. 8.

FIG. 11 is a plan view showing a semiconductor device which is another modification example relative to FIG. 8.

FIG. 12 is a plan view showing an example of a circuit layout in a semiconductor chip of the semiconductor device shown in FIG. 11, which is a modification example relative to FIG. 6.

FIG. 13 is an explanatory diagram showing an example of an electrically connected state between the plurality of circuits shown in FIG. 12 and the plurality of external terminals shown in FIG. 11.

FIG. 14 is a plan view showing an example of the power plane and the ground plane among the plurality of conductor planes of the mounting substrate of the electronic device on which the semiconductor device shown in FIG. 11 is mounted.

FIG. 15 is a plan view showing a semiconductor device which is a modification example relative to FIG. 11.

FIG. 16 is a plan view showing a semiconductor device which is another modification example relative to FIG. 8.

### DETAILED DESCRIPTION

### Explanation of Description Format, Basic Terminology, and Usage in Present Application

In the present application, embodiments will be described in a plurality of sections or the like when necessary for the sake of convenience. These sections or the like are not independent or separate from each other unless otherwise clearly specified, and one portion of an example corresponds to another detailed portion, a modification example or the like. In addition, redundant descriptions of similar portions will be omitted in principle. Further, each of the components in the embodiments is not always indispensable unless otherwise clearly specified, or it is theoretically limited to a given number, or it is obvious from the context that the component is indispensable.

Likewise, in the description of the embodiments and the like, the wording such as “X made of A” used in association with a material, a composition or the like does not exclude a component that contains elements other than A unless otherwise clearly specified or it is obvious from the context that the material, the composition or the like only contains A. For example, for any component, it may mean “X containing A as a main component” or the like. For example, a “silicon member” or the like is not limited to a member made of pure silicon but includes a member made of a SiGe (silicon-germanium) alloy or a multicomponent alloy containing silicon as a main component, and a member containing other additives and the like. In addition, a gold plating, a Cu layer, a nickel plating or the like is not limited to a member made of a pure component, and includes a member respectively containing gold, Cu, nickel or the like as a main component unless otherwise clearly specified.

Further, when referring to a specific numerical value or a quantity, the specific numerical value is given as an example unless otherwise clearly specified or it is obvious from the context that the value is given as an example.

In addition, in each of the drawings used to describe the embodiments, identical or similar portions are denoted by identical or similar symbols or reference signs, and redundant descriptions of thereof are omitted in principle.

Further, in the attached drawings, hatched lines and the like are occasionally omitted even if the drawing is a cross section if the hatched lines make the drawings complicated or a difference between a member and a void is obvious. In this context, contour lines of a background are occasionally omitted even for a closed circle in plan view if it is obvious from the descriptions or the like. Furthermore, hatched lines or stippled dots are occasionally added even if the drawing is not a cross section in order to clarify that the portion is not a void or in order to clarify a boundary of a region.

In the following description, the terms “power plane”, “ground plane”, or “conductor plane” may be used. “Plane” refers to a large-area conductor pattern. “Conductor plane” is a collective term for “power plane” and “ground plane” and refers to a large-area conductor pattern supplied with a fixed potential. “Power plane” refers to a large-area conductor pattern to which a power supply potential is supplied. “Ground plane” refers to a large-area conductor pattern to which a reference potential is supplied.

An area of the “conductor plane” varies in various examples, but compared to a “wiring pattern” that constitutes a signal transmission path, the area of the “conductor plane” is at least ten times larger than the area of the “wiring pattern.”

### Electronic Device

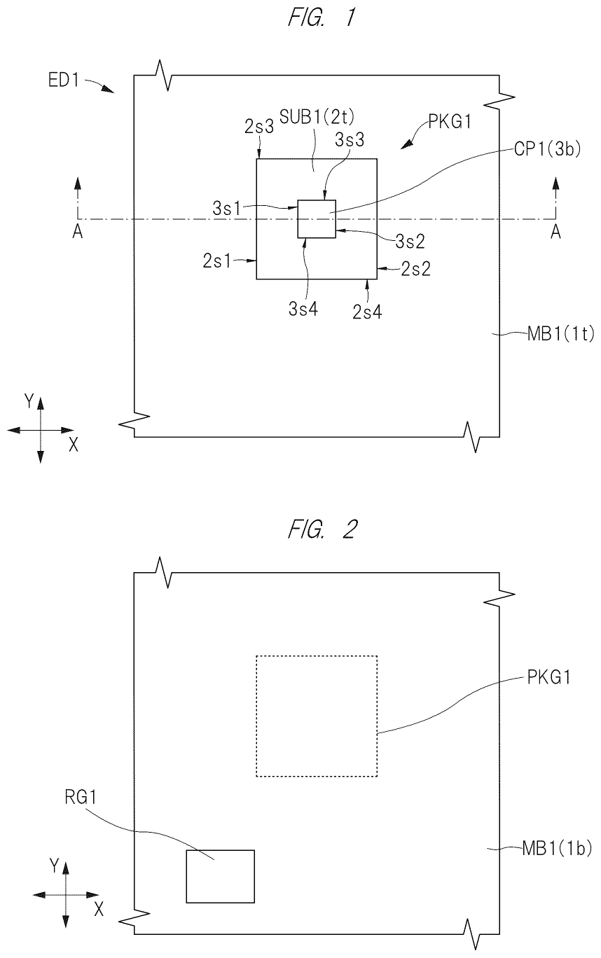

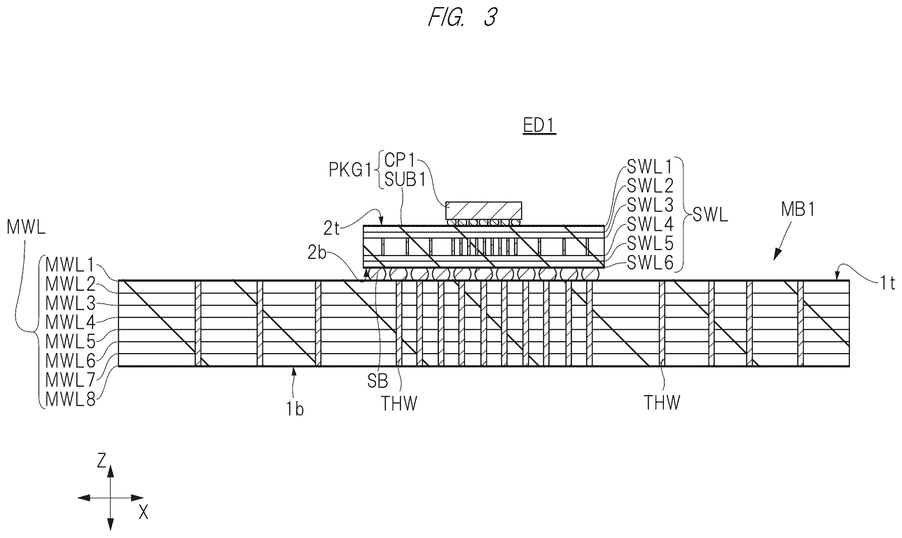

First, an electronic device of the present embodiment will be described. FIG. 1 is a plan view of a top surface of an electronic device according to the present embodiment. FIG. 2 is a plan view of a bottom surface of the electronic device shown in FIG. 1. FIG. 3 is a cross-sectional view along a line A-A of FIG. 1.

FIGS. 1 to 3 show either an X direction (see FIGS. 1 to 3), a Y direction (see FIGS. 1 and 2), or a Z direction (see FIG. 3). The Y direction intersects the X direction, and in the following description, the X direction and the Y direction are orthogonal to each other. The Z direction is perpendicular to both X and Y directions. In other words, the Z direction is a normal direction (i.e., perpendicular direction) to an X-Y plane containing the X and Y directions. In the following description, “thickness” generally refers to a length in the Z direction. Additionally, in the following description, “plan view” generally refers to the plan view when viewing the X-Y plane.

As shown in FIG. 1, an electronic device ED1 has a mounting substrate (wiring substrate) MB1 and a semiconductor device PKG1 mounted on the mounting substrate MB1. The mounting substrate MB1 has a top surface 1t and a bottom surface 1b opposite to the top surface (see FIG. 2). The semiconductor device PKG1 is mounted on the top surface 1t of the mounting substrate MB1.

Additionally, in the present embodiment and as shown in FIG. 2, a regulator (power supply component) RG1 is mounted on the bottom surface 1b of the mounting substrate MB1. The regulator RG1 is a power supply component capable of supplying potentials of various of values. For example, the potential required to operate each of the plurality of circuits of the semiconductor device PKG1 are supplied from the regulator RG1 to the mounting substrate MB1.

The semiconductor device PKG1 has an interposer substrate SUB1 and a semiconductor chip CP1 mounted on the interposer substrate SUB1. A detailed structure of the semiconductor device PKG1 will be described below.

Note that the mounting substrate MB1 and the interposer substrate SUB1 of the semiconductor device PKG1 are each wiring substrates. However, the degree of miniaturization of the conductor patterns forming a signal transmission path or a potential supply path differs between the mounting substrate MB1 and the interposer substrate SUB1.

Specifically, the interposer substrate SUB1 is a wiring substrate that functions as an interposer for electrically connecting the miniaturized semiconductor chip CP1 and the mounting substrate MB1. Signal transmission paths formed on the interposer substrate SUB1 are electrically connected to each electrode of the semiconductor chips CP1 arranged at narrow pitches. Therefore, it is necessary for conductor patterns forming the signal transmission paths of the interposer substrate SUB1 to be miniaturized compared to conductor patterns forming the signal transmission paths formed on the mounting substrate MB1.

The mounting substrate MB1 is a wiring substrate on which the semiconductor device PKG1 is mounted. FIG. 1 shows only the semiconductor device PKG1 as the electronic component mounted on the top surface 1t of the mounting substrate MB1. Additionally, FIG. 2 shows only the regulator RG1 as the electronic component mounted on the bottom surface 1b of the mounting substrate MB1.

However, There Are Various Modifications to the Electronic Component mounted on the mounting substrate MB1. For example, a plurality of electronic components including the semiconductor device PKG1 may be mounted on the top surface 1t of the mounting substrate MB1. Examples of electronic components other than the semiconductor device PKG1 and the regulator RG1 include passive components such as capacitor elements, resistor elements, or inductor elements.

As shown in FIG. 3, the mounting substrate MB1 has a plurality of wiring layers MWL stacked in a thickness direction of the mounting substrate MB1 (Z direction in FIG. 3). The thickness direction of the mounting substrate MB1 is a direction from one side to the other side of the mounting substrate MB1, between the top surface 1t and the bottom surface 1b. In the example shown in FIG. 3, the mounting substrate MB1 sequentially has wiring layers MWL1 to MWL8. The wiring layer MWL1 is a wiring layer closest to the top surface 1t among the plurality of wiring layers MWL. The wiring layer MWL8 is a wiring layer closest to the bottom surface 1b among the plurality of wiring layers MWL. Note that this eight-layer structure of the wiring layers shown in FIG. 3 is merely an example, and the number of stacked wiring layers MWL may vary, such as seven layers or fewer, or nine layers or more.

Additionally, the mounting substrate MB1 has a plurality of through-hole wirings THW formed so as to penetrate the plurality of wiring layers MWL. Each of the plurality of through-hole wirings THW is formed so as to penetrate from the wiring layer MWL1 to the wiring layer MWL8.

A wiring substrate in which the plurality of wiring layers MWL stacked like the mounting substrate MB1 are electrically connected via the through-hole wirings THW is called a through-hole multilayer substrate. When manufacturing the through-hole multilayer substrate, the required total number of wiring layers MWL are stacked, and the holes (through holes) are then formed so as to penetrate the plurality of wiring layers MWL. Subsequently, conductors are embedded in the through-holes to form the through-hole wirings THW.

Note that, in the case of the interposer substrate SUB1 shown in FIG. 3, among the plurality of stacked wiring layers SWL, the wiring layers SWL that are adjacent to each other in the thickness direction are connected via a via wiring. The through-hole wirings THW shown in FIG. 3 differ from the via wiring in that it is arranged across three or more wiring layers MWL. In FIG. 3, a six-layer structure including wiring layers SWL1 to SWL6 is shown as an example of the wiring layer SWL.

A wiring substrate in which the plurality of wiring layers SWL are electrically connected via the via wiring such as the interposer substrate SUB1 is called a build-up substrate. When manufacturing a build-up substrate, the via wiring is formed each time a wiring layer SWL is stacked. The manufacturing method for the build-up substrate is called the build-up process.

In the case of the through-hole multilayer substrate, interlayer conductive paths connecting the plurality of wiring layers MWL can be formed in a single step as described above, and thus, it is possible to improve manufacturing efficiency. As a result, manufacturing cost of the mounting substrate MB1 can be reduced. On the other hand, it is necessary for each of the plurality of wiring layers MWL to be designed considering the positions of the plurality of through-hole wirings THW. Therefore, constraints arise in the layout of the conductor pattern in each of the plurality of wiring layers MWL.

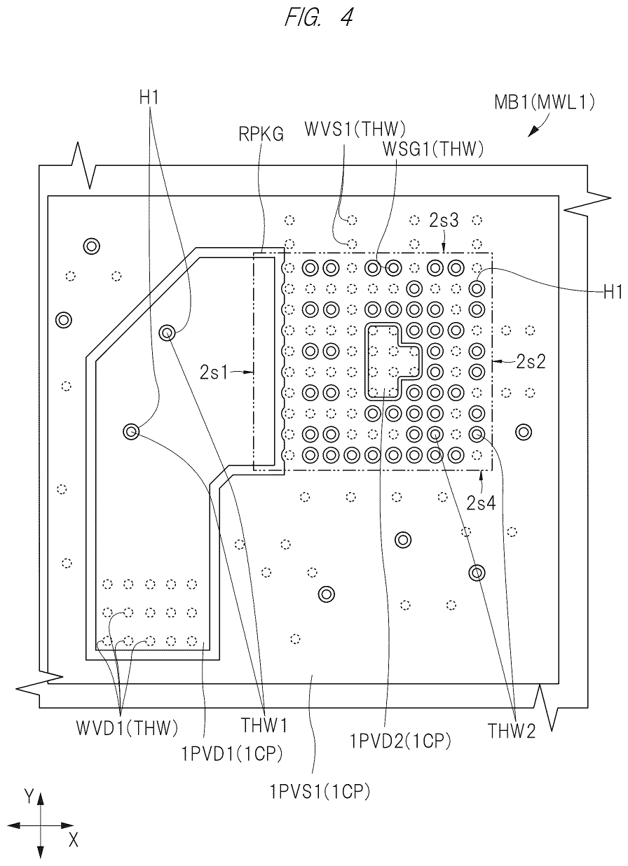

FIG. 4 is a plan view showing an example of a power plane and a ground plane among a plurality of conductor planes of the mounting substrate shown in FIG. 3. FIG. 4 shows a portion of the wiring layer MWL1 shown in FIG. 3 enlarged. In FIG. 4, a contour of a region RPKG overlapping the semiconductor device PKG1 shown in FIG. 3 is indicated by a two-point dashed line.

As shown in FIG. 4, a plurality of conductor patterns of the mounting substrate MB1 include a conductor plane 1CP for supplying a fixed potential such as a power supply potential and a reference potential. The conductor plane 1CP is a large-area conductor pattern. Interposing the large-area conductor plane 1CP in a supply path for the fixed potential allows an increase in a cross-sectional area of a current path. As a result, it is possible to stably supply the fixed potential to a power-consuming circuit.

FIG. 4 shows, among the plurality of conductor planes of the mounting substrate MB1, a power plane 1PVD1 constituting a supply path for the power supply potential, and a ground plane 1PVS1 constituting a supply path for the reference potential. Additionally, FIG. 4 shows a power plane 1PVD2 constituting a supply path for a power supply potential that differs from the potential supplied to the power plane 1PVD1.

Additionally, the plurality of through-hole wirings THW are arranged in the wiring layer MWL1. The plurality of through-hole wirings THW has a power supply potential through-hole wiring WVD1 for supplying the power supply potential, and a reference potential through-hole wiring WVS1 for supplying the reference potential (e.g., ground potential). Additionally, the plurality of through-hole wirings THW has a signal through-hole wiring WSG1 for transmitting signals.

Various potentials such as power supply potential, reference potential, signals or the like are supplied to the semiconductor device PKG1 shown in FIG. 3. Thus, as shown in FIG. 4, a large number of through-hole wirings THW are densely arranged in the region RPKG overlapping the semiconductor device PKG1 (see FIG. 3). In other words, the arrangement density of the through-hole wirings THW in the region RPKG is higher than the arrangement density of the through-hole wirings THW in a peripheral region of the region RPKG.

Therefore, a large number of openings H1 are formed in the ground plane 1PVS1 in the region RPKG. Additionally, it is difficult to make the power plane 1PVD2 arranged in the region RPKG sufficiently large in area.

On the other hand, in plan view, it is relatively easy to secure space outside the RPKG region where no other through-hole wiring THW for other potentials or signals is arranged. For example, in the example shown in FIG. 4, among the plurality of through-hole wirings THW arranged at positions overlapping the power plane 1PVD1, there are two through-hole wirings THW that are not power supply potential through-hole wirings WVD1. Thus, there are two openings H1 formed in the power plane 1PVD1.

From the perspective of stably supplying a fixed potential, it is preferable that the number of openings H1 formed in the power plane 1PVD1 be as few as possible. In particular, it is preferable that the number of openings H1 be as few as possible in the vicinity of an external terminal SB (see FIG. 3) where the semiconductor device PKG1 (see FIG. 3) is connected to the mounting substrate MB1. When the number of openings H1 is small, a degree of freedom for charge movement within the power plane 1PVD1 increases. In this case, even when there is a sudden increase in power demand, voltage drops are less likely to occur.

The electronic device ED1 of the present embodiment (see FIG. 3) reduces the number of openings H1 formed in the power plane 1PVD1 and increases the area of the power plane 1PVD1. This stabilizes the power supply potential supplied to the semiconductor device PKG1 (see FIG. 3) via the power plane 1PVD1.

For example, in the example shown in FIG. 4, the through-hole wirings that are positioned at locations overlapping the power plane 1PVD1 and are electrically isolated from the power plane 1PVD1 are referred to as through-hole wirings THW1. The through-hole wirings THW positioned at locations overlapping the semiconductor device PKG1 (see FIG. 3) are referred to as through-hole wirings THW2. In FIG. 4, the number of the through-hole wirings THW1 is fewer than the number of the second through-hole wirings THW2.

Note that, as described above, from the perspective of stabilizing the power supply potential, it is necessary to modify the structure of the semiconductor device PKG1. The next section will describe details of the structure of the semiconductor device PKG1.

### Semiconductor Device

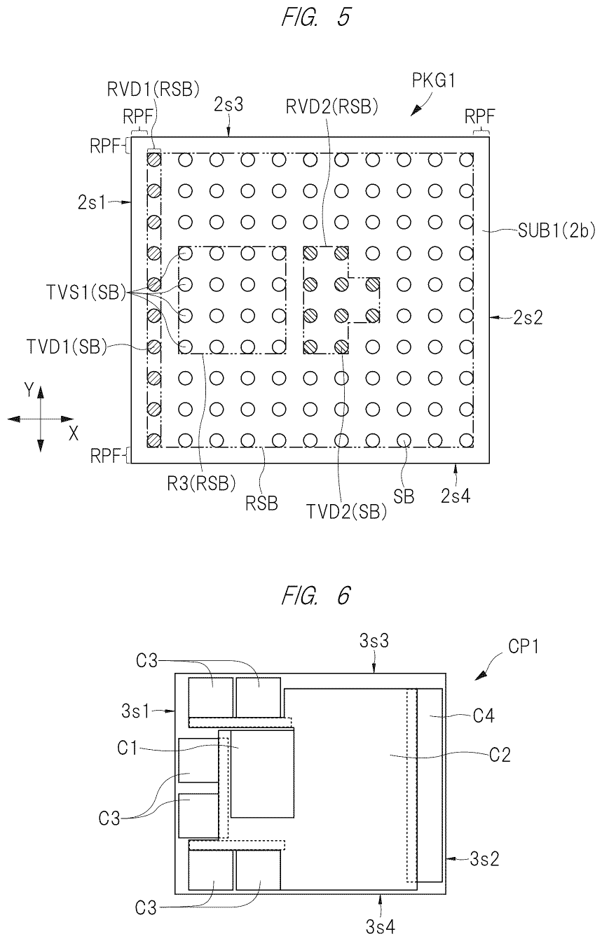

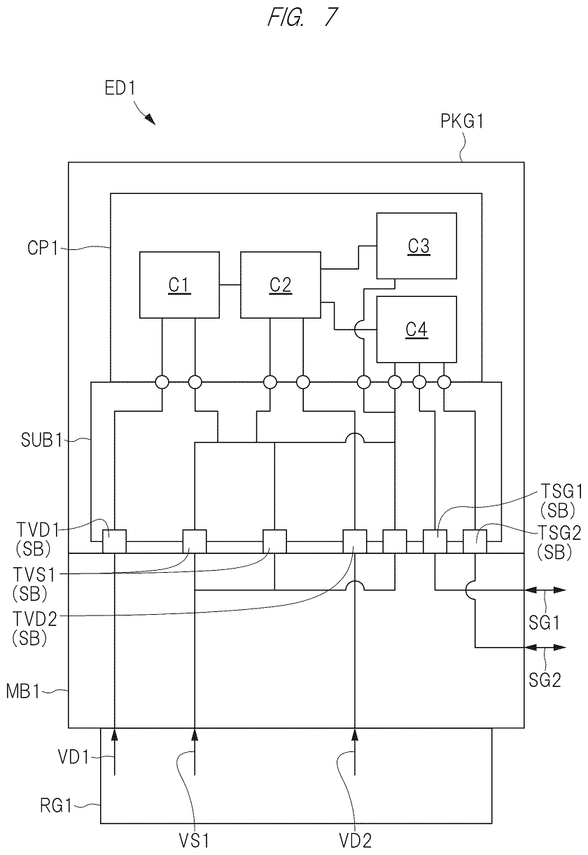

FIG. 1 is a plan view of a top surface of the electronic device of the present embodiment. FIG. 5 is a plan view of a bottom surface of the semiconductor device shown in FIG. 3, with hatched lines added to the power supply terminals TVD1 and TVD2 to make them easier to distinguish from other external terminals SB. FIG. 6 is an explanatory diagram showing an example of a layout of a plurality of circuits of the semiconductor chip shown in FIG. 3. FIG. 7 is an explanatory diagram showing an example of an electrically connected state between the plurality of circuits shown in FIG. 6 and the plurality of external terminals shown in FIG. 5.

As shown in FIGS. 1 and 3, the semiconductor device PKG1 has the semiconductor chip CP1, the interposer substrate SUB1, and the plurality of external terminals SB.

As shown in FIG. 5, a bottom surface 2b of the interposer substrate SUB1 is rectangular. In other words, the shape of the bottom surface 2b is rectangular when viewed from above. The bottom surface 2b includes an edge 2s1, an edge 2s2 opposite to the edge 2s1, an edge 2s3 extending in a direction perpendicular to the edges 2s1 and 2s2, and an edge 2s4 opposite to the edge 2s3.

Note that, as shown in FIG. 1, a top surface 2t of the interposer substrate SUB1 also has an edge 2s1, an edge 2s2, an edge 2s3, and an edge 2s4. Each edge of the bottom surface 2b shown in FIG. 5 overlaps the respective edge of the top surface 2t shown in FIG. 1.

Additionally, the semiconductor chip CP1 includes an edge 3s1, an edge 3s2 opposite to the edge 3s1, an edge 3s3 extending in a direction intersecting each of the edges 3s1 and 3s2, and an edge 3s4 opposite to the edge 3s3. The edge 3s1 is arranged along the edge 2s1. The edge 3s2 is arranged along the edge 2s2. The edge 3s3 is arranged along the edge 2s3. The edge 3s4 is arranged along the edge 2s4. Note that the edges of the semiconductor chip CP1 are also shown in FIG. 6.

The bottom surface 2b includes a terminal arrangement region RSB in which the plurality of external terminals SB are arranged, and a peripheral region RPF surrounding a periphery of the terminal arrangement region RSB. In plan view, the plurality of external terminals SB are arranged in alignment on the bottom surface 2b of the interposer substrate SUB1. In the example shown in FIG. 5, the plurality of external terminals SB are arranged in a matrix-like manner. Each of the plurality of external terminals SB is a solder ball formed from, for example, a ball-shaped solder.

As shown in FIG. 6, the semiconductor chip CP1 comprises a plurality of circuits. The plurality of circuits include a circuit C1 and a circuit C2. Additionally, in the example shown in FIG. 6, the plurality of circuits of the semiconductor chip CP1 include a plurality of circuits C3 and a circuit C4.

The circuit C1 shown in FIG. 6 is, for example, a CPU circuit. The CPU circuit is a circuit that reads and executes a program. The CPU circuit is a circuit for performing main arithmetic processing of a computer. The CPU circuit is electrically connected to peripheral circuits (e.g., circuit C3 and circuit C4) via a peripheral bus.

The plurality of circuits C3 are input/output circuits such as DDR SDRAMs (Double-Data-Rate Synchronous Dynamic Random Access Memory). The DDR SDRAM and the like are also referred to as main memory in relation to a cache memory described below.

The circuit C4 is a signal input/output circuit. Such an input/output circuit includes, for example, a SerDes circuit that converts between a serial transmission method and a parallel transmission method.

The circuit C2 is a core circuit (or is also referred to as a core logic circuit). However, the core circuit that constitutes the circuit C2 is distinct from the CPU circuit shown as the circuit C1. The circuit C2 includes a memory control circuit that controls an operation of the circuit C3. Additionally, the circuit C2 includes an input/output control circuit that controls an operation of the circuit C4. Additionally, the circuit C2 includes the above-described peripheral bus. Additionally, the circuit C2 includes an SRAM (Static Random Access Memory) circuit that can be used as a cache memory circuit.

Focusing on power consumption of each of the plurality of circuits shown in FIG. 6, the power consumption of the circuit C1 is the largest among the power consumption of each of the plurality of circuits of the semiconductor chip CP1. Additionally, the power consumption of the circuit C2 is the second largest among the power consumption of each of the plurality of circuits of the semiconductor chip CP1.

Although not shown, as a study example for the present embodiment, it is possible to consider an embodiment having a supply path for supplying a power supply potential to the circuit C1 which is the CPU circuit and a supply path for supplying power supply potential to the circuit C2 which is the core circuit in common.

However, from the perspective of stably supplying power to the circuit C1 having the largest power consumption, it is preferable to provide a dedicated path for supplying the power supply potential to the circuit C1. For example, providing a dedicated power supply path for the circuit C1 makes it possible to prevent a sudden power supply shortage to the circuit C1 depending on the operation state of the other circuits.

As shown in FIG. 7, in the case of the present embodiment, a supply path for a power supply potential VD1 and a supply path for a power supply potential VD2 are electrically isolated from each other. The power supply potential VD1 and the power supply potential VD2 are at different potentials from each other. However, as a modification example, the power supply potential VD1 and the power supply potential VD2 may be at the same potential. Even when the power supply potential VD1 and the power supply potential VD2 are at the same potential, the supply path for the power supply potential VD1 and the supply path for the power supply potential VD2 are electrically isolated from each other. Thus, the present embodiment is preferable from the perspective of stably supplying power to the circuit C1 having the largest power consumption.

Note that the power supply paths required to operate each of the plurality of circuits C3 and the circuit C4 shown in FIG. 6 are provided separately from the supply path for the power supply potential VD1 and the power supply path for the power supply potential VD2. However, these are omitted in FIG. 7.

As shown in FIG. 7, each of the plurality of external terminals SB of the semiconductor device PKG1 includes a power supply terminal TVD1 capable of supplying the power supply potential VD1 supplied from an external source to the circuit C1. Note that, in FIG. 7, a single power supply terminal TVD1 is schematically shown, but as shown in FIG. 5, the semiconductor device PKG1 comprises a plurality of power supply terminals TVD1. Additionally, in the example shown in FIG. 7, each of the plurality of external terminals SB further includes a power supply terminal TVD2 capable of supplying the power supply potential VD2 supplied from an external source to the circuit C2. As shown in FIG. 5, the semiconductor device PKG1 comprises a plurality of power supply terminals TVD2.

As shown in FIG. 5, the terminal arrangement region RSB includes a region RVD1 closest to the edge 2s1 of the interposer substrate SUB1 and extending along the edge 2s1. Additionally, in the region RVD1, only the power supply terminals TVD1 among the plurality of external terminals SB are arranged so as to be adjacent to each other.

Here, the power supply potential VD1 is supplied via the power plane 1PVD1 formed in the wiring layer MWL1 among the plurality of conductor planes 1CP of the mounting substrate MB1 described with reference to FIG. 4. In a transparent plan view, the power plane 1PVD1 is arranged so as to span across the edge 2s1 among the four edges of the bottom surface 2b (see FIG. 5) of the interposer substrate SUB1 (see FIG. 5) of the semiconductor device PKG1 (see FIG. 5).

As shown in FIG. 5, when only the plurality of power supply terminals TVD1 are arranged so as to be adjacent to each other in the region RVD1, no other types of external terminals are arranged in the region RVD1. Thus, in the power plane 1PVD1 shown in FIG. 4, no opening H1 is formed in a portion arranged in the region RPKG that overlaps the semiconductor device PKG1 shown in FIG. 3. In other words, in the case of the present embodiment, in the power plane 1PVD1 (see FIG. 4) no opening H1 (see FIG. 4) is formed in the portion arranged in the vicinity of the plurality of power supply terminals TVD1 (see FIG. 5). Thus, a degree of freedom for charge movement between the plurality of power supply terminals TVD1 increases, making it possible to stably supply the power supply potential VD1 to the circuit C1 shown in FIG. 7.

As described above, the circuit C1 is a CPU circuit. The CPU circuit may require a significant change in power depending on the timing of arithmetic processing. For example, consider a case where the current flowing through some of the power supply terminals TVD1 increases by a sudden increase in the power required by the CPU circuit.

When the current flowing through some of the plurality of power supply terminals TVD1 increases, the charge in the periphery of the power supply terminals TVD1 becomes insufficient. At this time, if the power plane 1PVD1 (see FIG. 4) is arranged in the vicinity of the plurality of power supply terminals TVD1, the insufficient charge is supplied from the periphery of the power supply terminals TVD1, through which a large current flows, via the power plane 1PVD1.

However, when the opening H1 (see FIG. 4) is formed in the power plane 1PVD1 (see FIG. 4), charge movement may be impeded by the opening H1, causing a sudden voltage drop.

On the other hand, in the case of the present embodiment and as shown in FIG. 4, no opening H1 is formed in the power plane 1PVD1 in the region RPKG. Thus, charge movement is not impeded, and it is possible to suppress an occurrence of voltage drop. That is, it is possible to stably supply the power supply potential VD1 to the circuit C1 shown in FIG. 7.

Note that there may be various modification examples that differ in the number of power supply terminals TVD1 arranged continuously in the region RVD1 depending on the arrangement pitch of the external terminals SB and the size of the power plane 1PVD1 shown in FIG. 4. However, from the perspective of stabilizing the power supply potential, it is necessary that at least the plurality of power supply terminals TVD1 are arranged adjacent to each other. Additionally, it is preferable that five or more power supply terminals TVD1 are arranged continuously. In the example shown in FIG. 5, ten power supply terminals TVD1 are arranged continuously.

Additionally, as described above with reference to FIG. 6, the plurality of circuits of the semiconductor chip CP1 further includes the circuit C2. As shown in FIGS. 5 and 7, the plurality of external terminals SB further includes the plurality of power supply terminals TVD2 (see FIG. 5) capable of supplying the power supply potential VD2 (see FIG. 7) supplied from an external source to the circuit C2 (see FIG. 7). As shown in FIG. 5, the terminal arrangement region RSB includes a region RVD2 farther from the region RVD1 when viewed from the edge 2s1. The plurality of power supply terminals TVD2 are arranged in the region RVD2.

As shown in FIG. 5, the power supply terminals TVD2 are densely arranged in the region RVD2. In other words, the power supply terminals TVD2 are collectively arranged in the region RVD2. Additionally, as shown in FIG. 4, the power plane 1PVD2 constituting the supply path for the power supply potential VD2(see FIG. 7) is arranged in the wiring layer MWL1 of the mounting substrate MB1.

However, as shown in FIG. 5, the external terminals SB other than the power supply terminals TVD2 are arranged in the periphery of the region RVD2. Thus, as shown in FIG. 4, an area of the power plane 1PVD2 cannot be made larger than an area of the power plane 1PVD1. Additionally, a configuration in which the power plane 1PVD2 is arranged on a wiring layer that differs from the wiring layer MWL1 (e.g., any of the wiring layers MWL2 to MWL8 shown in FIG. 3). However, as shown in FIG. 4, a large number of through-hole wirings THW are arranged in the region RPKG. Thus, even if the power plane 1PVD2 is arranged on a wiring layer that differs from the wiring layer MWL1 shown in FIG. 4, a large number of openings H1 will be formed in the power plane 1PVD2.

Therefore, as described above, from the perspective of stably supplying the fixed potential, the supply path for the power supply potential VD1 shown in FIG. 7 is superior to the supply path for the power supply potential VD2. In the case of the present embodiment, focusing on the power consumption of the plurality of circuits of the semiconductor chip CP1 shown in FIG. 7, priority is given to the supply path for the power supply potential connected to the circuit C1 having the highest power consumption. This is because a sudden voltage drop is unlikely to occur in the circuit C2 which has lower power consumption than the circuit C1.

Additionally, as described above with reference to FIG. 7, the plurality of external terminals SB further includes a reference potential terminal TVS1 capable of supplying the reference potential VS1 supplied from an external source to the circuits C1 and C2.

As shown in FIG. 5, the terminal arrangement region RSB further includes a region R3 located between the regions RVD1 and RVD2. At least some of the plurality of reference potential terminals TVS1 are arranged in the region R3.

Note that, as shown in FIG. 6, the circuit C1 is arranged closer to the edge 3s1 than the edge 3s2 among the four edges of the semiconductor chip CP1. As shown in FIG. 1, the edge 3s1 of the semiconductor chip CP1 is arranged along the edge 2s1 of the interposer substrate SUB1. As shown in FIG. 5, the plurality of power supply terminals TVD1 are arranged in the region RVD1 closest to the edge 2s1. In this case, arranging the circuit C1 close to the edge 3s1 makes it possible to shorten a distance of the supply path for the power supply potential VD1 (see FIG. 7).

### Relationship Between Signal Terminals and Power Supply Terminals

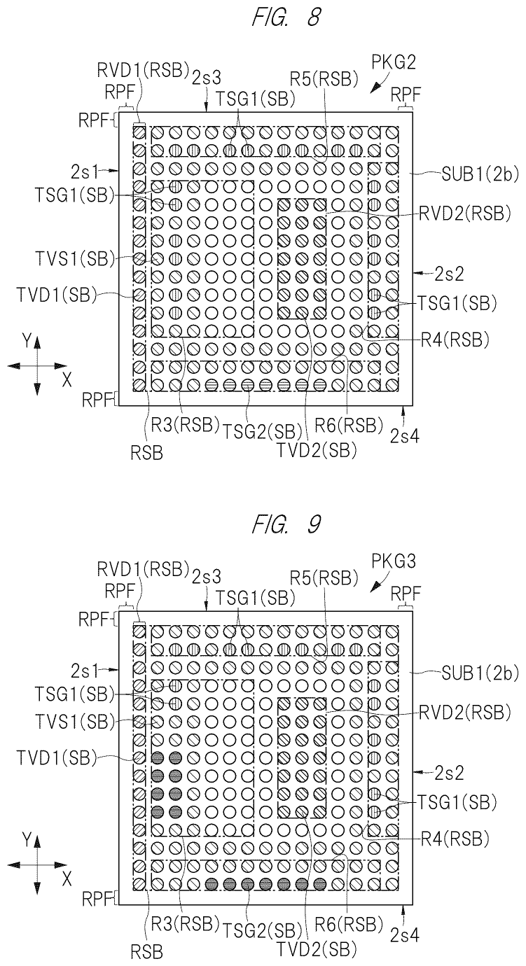

Next, relative positions between the plurality of power supply terminals TVD1 shown in FIG. 5 and the external terminals SB for signal transmission will be described using several embodiments. FIG. 8 is a plan view showing an example of relative positions of the power supply terminal, the reference potential terminal, and the differential signal terminal pair among the plurality of external terminals of the semiconductor device. Although FIG. 8 is a plan view, hatched lines are added to some of the external terminals SB to make it easier to identify the types of external terminals SB. The same applies to FIGS. 9 to 11, 15, and 16 described below.

The plurality of external terminals SB of a semiconductor device PKG2 shown in FIG. 8 are arranged as follows. Specifically, regions RVD1 and R3 are adjacent to each other with no other region interposed therebetween. The plurality of external terminals SB further include a plurality of differential signal terminal pairs TSG1. The differential signal terminal pairs TSG1 constitute differential pairs capable of transmitting signals SG1 which are differential signals (see FIG. 7) at a first signal transmission speed.

The plurality of reference potential terminals TVS1 are arranged so as to surround the periphery of each of the differential signal terminal pairs TSG1, and so as to be adjacent to each of the plurality of differential signal terminal pairs TSG1. Some of the plurality of reference potential terminals TVS1 arranged in the periphery of each of the plurality of differential signal terminal pairs TSG1 are adjacent to one of the plurality of power supply terminals TVD1 arranged in the region RVD1.

As a signal transmission method, the differential signals and single-ended signals are compared. As a method for increasing the signal transmission speed, there is a method of reducing an amplitude of the signal voltage. Additionally, in recent years, there are provided techniques that increase information content contained in the amplitude of the signal voltage, such as PAM4 (4-level Pulse Amplitude Modulation), to achieve high-speed signal transmission.

In the case of the single-ended signals, reducing the amplitude of the signal voltage increases the influence of noise. On the other hand, in the case of the differential signals, a potential difference between the paired transmission paths is utilized, and thus, when the same noise is applied to both of the paired transmission paths, the noise can be canceled. In other words, the differential signals have a higher noise immunity than the single-ended signals when the amplitude of the signal voltage is reduced. Thus, the differential signals are used as the transmission path for high-speed signals.

However, in order to improve transmission quality of the differential signals, it is necessary to consider the characteristic impedance of the transmission path. The characteristic impedance of the transmission path for the differential signals is defined by factors such as a distance between the transmission paths, a distance between the transmission path and the peripheral conductor pattern, and polarity of the current flowing in the transmission path. In order to improve transmission quality of the differential signals, it is preferable to avoid creating impedance discontinuities in the transmission path for the differential signals. Thus, it is preferable that the distance between the transmission paths is kept constant, and that the conductor pattern in which the fixed potential flows is arranged at a constant distance in the periphery of the transmission path.

In the example shown in FIG. 8, the reference potential terminal TVS1 that supplies the ground potential is arranged between each of the plurality of differential signal terminal pairs TSG1 and the power supply terminals TVD1. Thus, the influence of the plurality of power supply terminals TVD1 makes it possible to suppress an occurrence of impedance discontinuities in the transmission path for the differential signals. As a result, it is possible to improve the quality of the differential signals transmitted at high speeds.

Note that, in the mounting substrate MB1 (see FIG. 1), when the wiring layout for signal transmission is considered, it is preferable that the signal transmission terminal is arranged in a position close to an outermost periphery of the terminal arrangement region RSB shown in FIG. 8. In the example shown in FIG. 8, the terminal arrangement region RSB includes a region R4 extending along the edge 2s2, a region R5 extending along the edge 2s3, and a region R6 extending along the edge 2s4. Some of the plurality of differential signal terminal pairs TSG1 are arranged in at least one of the regions R4, R5, and R6. In the example shown in FIG. 8, the plurality of differential signal terminal pairs TSG1 are arranged in each of the regions R4 and R5.

As described above, from the perspective of improving the quality of differential signals, it is preferable that the periphery of the differential signal terminal pairs TSG1 is surrounded by the reference potential terminal TSV1. Therefore, in the outermost periphery of the terminal arrangement region RSB, i.e., in the region closest to the edge 2s2 and the region closest to the edge 2s3, the plurality of reference potential terminals TSV1 are arranged continuously. The differential signal terminal pairs TSG1 are arranged in the second column from the outer periphery.

FIG. 9 is a plan view showing a semiconductor device which is a modification example relative to FIG. 8. The plurality of external terminals SB of a semiconductor device PKG3 shown in FIG. 9 differ from those of the semiconductor device PKG2 shown in FIG. 8 in the following points.

The plurality of external terminals SB further include a plurality of signal terminals TSG2. The signal terminals TSG2 are terminals capable of transmitting a signal SG2 (see FIG. 7) at a second signal transmission speed. The second signal transmission speed is slower than the first signal transmission speed which is the transmission speed of the signal SG1 shown in FIG. 7. The signal SG2 is, for example, a single-ended signal. Note that the signal terminals TSG2 are also shown in the example shown in FIG. 8. The plurality of signal terminals TSG2 are arranged in the region R6.

In the case of the semiconductor device PKG3 shown in FIG. 9, the plurality of signal terminals TSG2 are arranged in the region R3. The reference potential terminal TVS1 is interposed between the plurality of signal terminals TSG2 and the plurality of differential signal terminal pairs TSG1.

Depending on the layout of the terminals for signal transmission, the signal terminals TSG2 may be arranged close to the differential signal terminal pairs TSG1 used for high-speed transmission. In this case, it is necessary to avoid interference between the signal SG2 flowing in the signal terminals TSG2 (see FIG. 7) and the signal SG1 flowing in the differential signal terminal pairs TSG1 (see FIG. 7). As in the present modification example, interposing the reference potential terminal TVS1 between the differential signal terminal pair TSG1 and the signal terminals TSG2 makes it possible to suppress the above-described interference.

As described above, the signal SG2 shown in FIG. 7 is a signal transmitted at a speed lower than the signal SG1. Thus, sufficiently increasing the signal voltage makes it possible to reduce the influence of noise. In other words, any external terminal SB can be arranged in the periphery of the signal terminal TSG2. In the example shown in FIG. 9, some of the plurality of signal terminals TSG2 are adjacent to one of the plurality of power supply terminals TVD1 arranged in the region RVD1. Note that, although not shown in the figure, as a modification example relative to the example shown in FIG. 9, the reference potential terminal TVS1 may be interposed between the plurality of signal terminals TSG2 and the plurality of power supply terminals TVD1 arranged in the region RVD1.

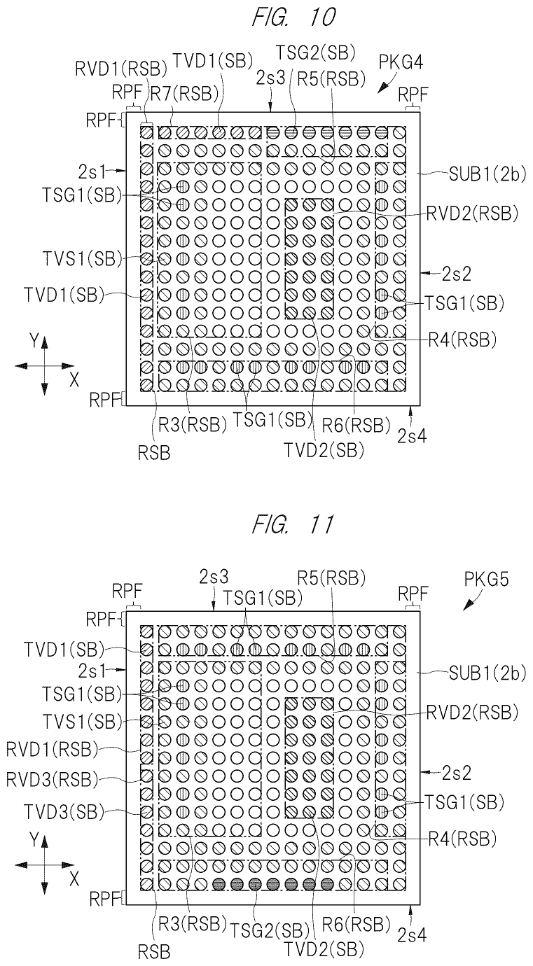

FIG. 10 is a plan view showing a semiconductor device which is another modification example relative to FIG. 8. The plurality of external terminals SB of a semiconductor device PKG4 shown in FIG. 10 differ from those of the semiconductor device PKG2 shown in FIG. 8 in the following points.

The terminal arrangement region RSB further includes a region R7 closest to the edge 2s3 of the interposer substrate SUB1 and extending along the edge 2s3. In the region R7, only the plurality of power supply terminals TVD1 among the plurality of external terminals SB are arranged so as to be adjacent to each other. In other words, in the case of the semiconductor device PKG4, plurality of power supply terminals TVD1 are arranged along the plurality of edges.

In a case where the power supply terminals TVD1 are arranged along the plurality of edges as in the present modification example, it is possible to increase the area of the power plane 1PVD1 shown in FIG. 4 in the vicinity of the power supply terminal TVD1.

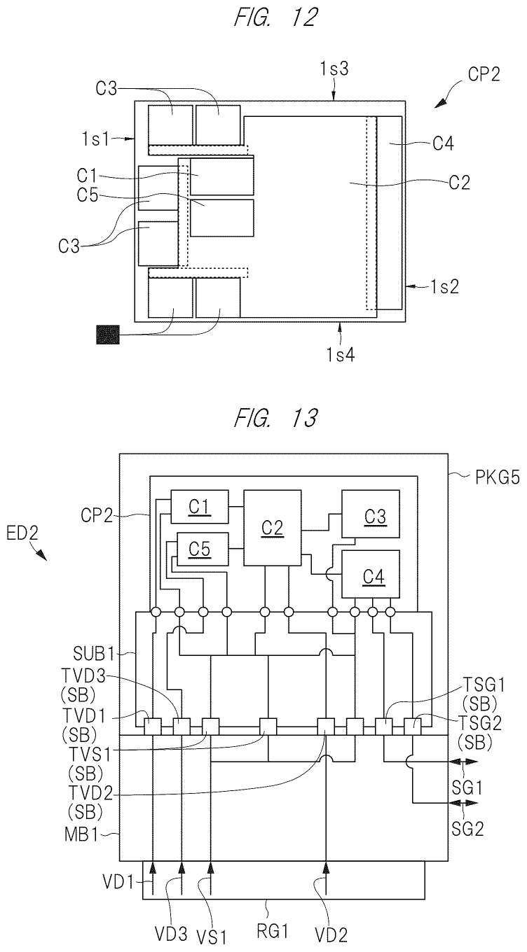

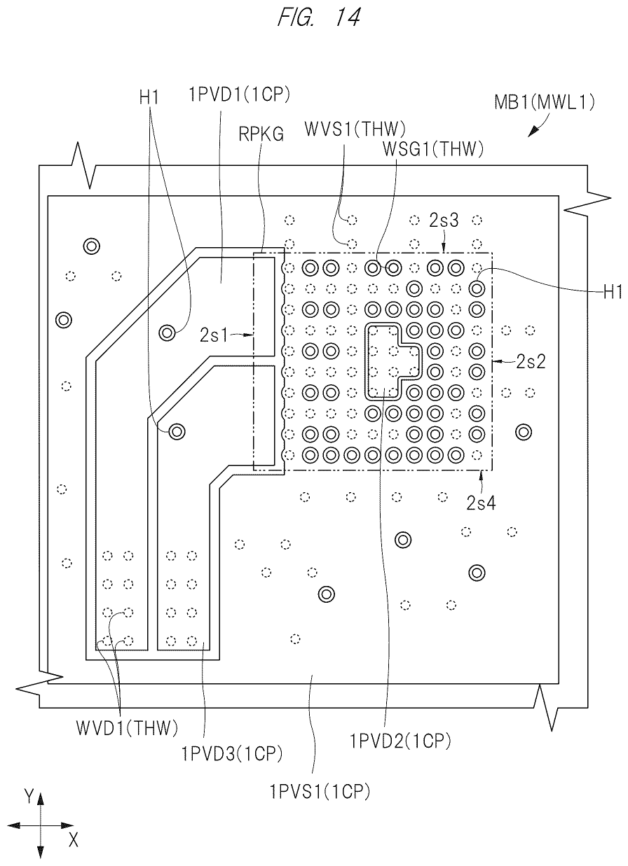

FIG. 11 is a plan view showing a semiconductor device which is another modification example relative to FIG. 8. FIG. 12 is a plan view showing an example of a circuit layout in a semiconductor chip of the semiconductor device shown in FIG. 11, which is a modification example relative to FIG. 6. FIG. 13 is an explanatory diagram showing an example of an electrically connected state between the plurality of circuits shown in FIG. 12 and the plurality of external terminals shown in FIG. 11. FIG. 14 is a plan view showing an example of the power plane and the ground plane among the plurality of conductor planes of the mounting substrate of the electronic device on which the semiconductor device shown in FIG. 11 is mounted. The plurality of external terminals SB of a semiconductor device PKG5 shown in FIG. 11 differ from those of the semiconductor device PKG2 shown in FIG. 8 in the following points.

The semiconductor device PKG5 shown in FIG. 11 has a semiconductor chip CP2 shown in FIG. 12. The plurality of circuits of the semiconductor chip CP2 further includes a circuit C5 as shown in FIGS. 12 and 13. The circuit C5 is, for example, a second CPU circuit capable of performing an on/off operation independently from the circuit C1 which is the CPU circuit. Since the circuit C5 is capable of performing the on/off operation independently from the circuit C1, there are cases where only the circuit C1 is operating, both circuits C1 and C5 are operating simultaneously, and only the circuit C5 is operating.

In the case where the circuits C1 and C5 perform the on/off operation independently, it is necessary for the power supply path of the circuits C1 and C5 to be separated. In addition, even in a case where the on/off operation is not performed independently, power consumption of the circuit C5 in operation is the same as that of the circuit C1 or is the second largest among the power consumption of each of the plurality of circuits of the semiconductor chip CP1. Therefore, it is preferable that the power supply paths to the two CPU circuits with the largest power consumption are separated. This is to prevent the power demand of one CPU circuit from affecting the power supply to the other CPU circuit.

As shown in FIG. 13, the plurality of external terminals SB further include a plurality of power supply terminals TVD3 capable of supplying a power supply potential VD3 supplied from an external source to the circuit C5. The power supply potential VD3 may be at the same potential as the power supply potential VD1 or may be at a different potential from the power supply potential VD1. In either case, the power supply terminals TVD3 are electrically isolated from the power supply terminals TVD1.

As shown in FIG. 11, the terminal arrangement region RSB includes a region RVD3 having a distance from the edge 2s1 of the interposer substrate SUB1 equal to that of the region RVD1 and extending along the edge 2s1. In the region RVD3, only the plurality of power supply terminals TVD3 among the plurality of external terminals SB are arranged so as to be adjacent to each other.

In the case of the present modification example, each of the plurality of power supply terminals TVD1 and the plurality of power supply terminals TVD3 are arranged on the outermost periphery of the terminal arrangement region RSB. The plurality of power supply terminals TVD1 are connected to the power plane 1PVD1 shown in FIG. 14. The plurality of power supply terminals TVD3 are connected to the power plane 1PVD3 shown in FIG. 14. Additionally, each of the power planes 1PVD1 and 1PVD3 do not overlap the through-hole wiring TWH in the region RPKG. That is, each of the plurality of power supply terminals TVD1 and TVD3 is connected to a power plane with a large area in the vicinity of the terminals. Thus, it is possible to stably supply a potential to each of the plurality of power supply terminals TVD1 and TVD3.

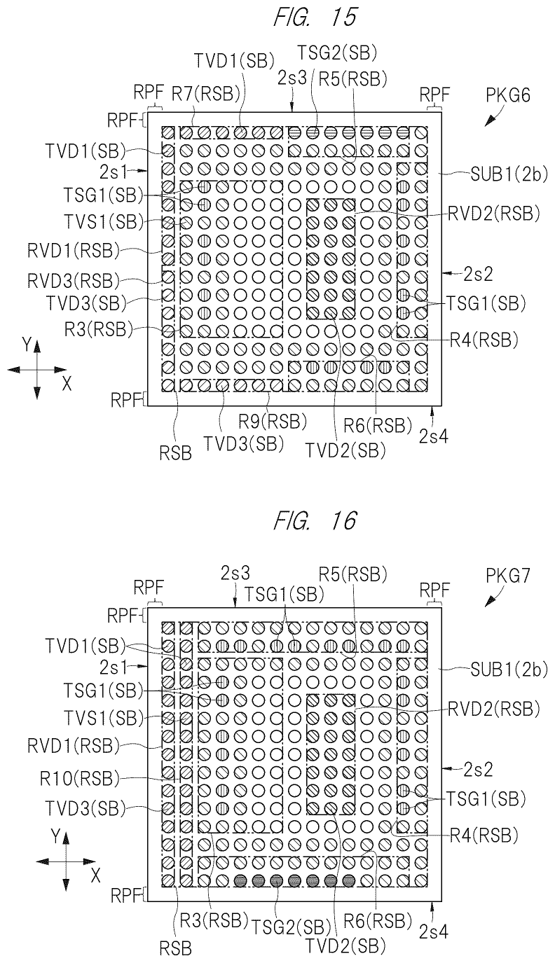

Note that, in a case where a semiconductor chip with a plurality of CPU circuits is used such as the semiconductor chip CP2 shown in FIG. 12, a modification example combining the embodiment shown in FIG. 11 and the embodiment shown in FIG. 10 is particularly effective. FIG. 15 is a plan view showing a semiconductor device which is a modification example relative to FIG. 11.

The plurality of external terminals SB of a semiconductor device PKG6 shown in FIG. 15 differs from those of the semiconductor device PKG5 shown in FIG. 11 in the following points.

In the example shown in FIG. 15, the terminal arrangement region RSB further includes regions R7 and R9. The region R7 is closest to the edge 2s3 of the interposer substrate SUB1 and extends along the edge 2s3. The region R9 is closest to the edge 2s4 of the interposer substrate SUB1 and extends along the edge 2s4. In the region R7, only the plurality of power supply terminals TVD1 among the plurality of external terminals SB are arranged so as to be adjacent to each other. In the region R9, only the plurality of power supply terminals TVD3 among the plurality of external terminals SB are arranged so as to be adjacent to each other.

In the case of the present modification example, the plurality of power supply terminals TVD1 and the plurality of power supply terminals TVD3 are each arranged along two edges. In this case, compared to the semiconductor device PKG5 shown in FIG. 11, it is possible to increase the number of the plurality of power supply terminals TVD1 and the plurality of power supply terminals TVD3.

Additionally, although each of the embodiments above have been described as having the plurality of power supply terminals TVD1 arranged only at the outermost periphery of the terminal arrangement region RSB, a modification example may have some of the plurality of power supply terminals TVD1 arranged outside the outermost periphery of the terminal arrangement region RSB, as in a semiconductor device PKG7 shown in FIG. 16. FIG. 16 is a plan view showing another modification example relative to FIG. 8.

The plurality of external terminals SB of the semiconductor device PKG7 shown in FIG. 16 differ from those of the semiconductor device PKG2 shown in FIG. 8 in the following points. The terminal arrangement region RSB further includes a region R10. The region R10 is adjacent to the region RVD1 and is located between the region R3 and the region RVD1. The region R10 extends along the region RVD1. In the region R10, only the plurality of power supply terminals TVD1 among the plurality of external terminals SB are arranged so as to be adjacent to each other.

In other words, in the present modification example, each of the plurality of power supply terminals TVD1 is arranged in two continuous rows along the edge 2s1. In a case where only the power supply terminals TVD1 are arranged in each of the adjacent regions RVD1 and R10 in such a manner, it is possible to further increase the area of the power plane 1PVD1 in the region RPKG shown in FIG. 4.

Note that, although FIG. 16 shows an embodiment in which each of the plurality of power supply terminals TVD1 is arranged in two rows, the number of rows may be three or more.

In the foregoing, the invention made by the present inventors has been concretely described on the basis of the embodiments. However, it is needless to say that the present invention is not limited to the foregoing embodiments, and various modifications can be made within the scope of the present invention.

For example, the above-described plurality of modification examples may be combined with each other.

Additionally, FIG. 4 shows the electronic device ED1 on which the semiconductor device PKG1 shown in FIG. 5 is mounted, and FIG. 14 shows an electronic device ED2 on which the semiconductor device PKG5 shown in FIG. 11 is mounted. However, there are various modification examples of the electronic device. For example, although not shown, an electronic device comprising any of the plurality of semiconductor devices described with reference to FIGS. 8 to 16 is capable of stably supplying the power supply potential VD1 (see FIG. 7).

What is claimed is:

1. A semiconductor device comprising:
a semiconductor chip having a plurality of circuits including a first circuit;
an interposer substrate including a first surface on which the semiconductor chip is mounted, and a second surface opposite to the first surface and being rectangular in shape when viewed from above; and
a plurality of external terminals arranged in alignment on the second surface of the interposer substrate,
wherein the plurality of external terminals include a plurality of first power supply terminals capable of supplying a first power supply potential supplied from an external source to the first circuit,
wherein the second surface includes a terminal arrangement region in which the plurality of external terminals are arranged, and a peripheral region surrounding a periphery of the terminal arrangement region,
wherein the terminal arrangement region includes a first region closest to a first edge of the interposer substrate and extending along the first edge,
wherein, in the first region, only the plurality of first power supply terminals among the plurality of external terminals are arranged so as to be adjacent to each other, and
wherein power consumption of the first circuit is the largest among the power consumption of each of the plurality of circuits of the semiconductor chip.

2. The semiconductor device according to claim 1,
wherein the plurality of circuits of the semiconductor chip further include a second circuit,
wherein the plurality of external terminals further include a plurality of second power supply terminals capable of supplying a second power supply potential supplied from an external source to the second circuit,
wherein the terminal arrangement region includes a second region farther from the first region when viewed from the first edge, and
wherein the plurality of second power supply terminals are arranged in the second region.

3. The semiconductor device according to claim 2,
wherein the terminal arrangement region further includes a third region located between the first region and the second region,
wherein the plurality of external terminals further include a plurality of reference potential terminals capable of supplying a reference potential supplied from an external source to the first and second circuits, and
wherein the plurality of reference potential terminals are arranged in the third region.

4. The semiconductor device according to claim 3,
wherein the first region and the third region are adjacent to each other with no other region interposed therebetween,
wherein the plurality of external terminals further include a plurality of first differential signal terminal pairs capable of transmitting a first differential signal at a first signal transmission speed,
wherein the plurality of reference potential terminals are arranged so as to surround a periphery of each of the plurality of first differential signal terminal pairs and be adjacent to each of the plurality of first differential signal terminal pairs, and
wherein some of the plurality of reference potential terminals arranged in the periphery of each of the plurality of first differential signal terminal pairs are adjacent to one of the plurality of first power supply terminals arranged in the first region.

5. The semiconductor device according to claim 4,
wherein the plurality of external terminals further include a plurality of first signal terminals capable of transmitting the first signal at a second signal transmission speed slower than the first signal transmission speed,
wherein the plurality of first signal terminals are arranged in the third region, and
wherein the reference potential terminals are interposed between the plurality of first signal terminals and the plurality of first differential signal terminal pairs.

6. The semiconductor device according to claim 5,
wherein the plurality of first signal terminals are adjacent to one of the plurality of first power supply terminals arranged in the first region.

7. The semiconductor device according to claim 4,
wherein the interposer substrate includes the first edge, a second edge opposite to the first edge, a third edge extending in a direction intersecting each of the first edge and the second edge, and a fourth edge opposite to the third edge,
wherein the terminal arrangement region includes a fourth region extending along the second edge, a fifth region extending along the third edge, and a sixth region extending along the fourth edge, and
wherein some of the plurality of first differential signal terminal pairs are arranged in at least one of the fourth region, the fifth region, and the sixth region.

8. The semiconductor device according to claim 3,
wherein the interposer substrate includes the first edge, a second edge opposite to the first edge, a third edge extending in a direction intersecting each of the first edge and the second edge, and a fourth edge opposite to the third edge,
wherein the terminal arrangement region further includes a seventh region closest to the third edge of the interposer substrate and extending along the third edge, and
wherein, in the seventh region, only the plurality of first power supply terminals among the plurality of external terminals are arranged so as to be adjacent to each other.

9. The semiconductor device according to claim 2,
wherein the plurality of circuits of the semiconductor chip includes:
a CPU circuit;
a plurality of memory circuits; and
a plurality of input/output circuits,
wherein the first circuit is the CPU circuit, and
wherein the second circuit includes a circuit configured to control one of the plurality of memory circuits and the plurality of input/output circuits.

10. The semiconductor device according to claim 2,
wherein the plurality of circuits of the semiconductor chip further include a third circuit,
wherein the plurality of external terminals further include a plurality of third power supply terminals capable of supplying a third power supply potential supplied from an external source to the third circuit,
wherein the terminal arrangement region includes an eighth region having a distance from the first edge of the interposer substrate equal to that of the first region and extending along the first edge,
wherein, in the eighth region, only the plurality of third power supply terminals among the plurality of external terminals are arranged so as to be adjacent to each other, and
wherein power consumption of the third circuit is the same as that of the first circuit or is the second largest among the power consumption of each of the plurality of circuits of the semiconductor chip.

11. The semiconductor device according to claim 10,
wherein the interposer substrate includes the first edge, a second edge opposite to the first edge, a third edge extending in a direction intersecting each of the first edge and the second edge, and a fourth edge opposite to the third edge,
wherein the terminal arrangement region further includes:
a seventh region closest to the third edge of the interposer substrate and extending along the third edge; and
a ninth region closest to the fourth edge of the interposer substrate and extending along the fourth edge,
wherein, in the seventh region, only the plurality of first power supply terminals among the plurality of external terminals are arranged so as to be adjacent to each other, and
wherein, in the ninth region, only the plurality of third power supply terminals among the plurality of external terminals are arranged so as to be adjacent to each other.

12. The semiconductor device according to claim 10,
wherein the first circuit is a first CPU circuit, and
wherein the third circuit is a second CPU circuit capable of performing an on/off operation independently from the first CPU circuit.

13. The semiconductor device according to claim 2,
wherein the terminal arrangement region further includes:
a third region located between the first region and the second region; and
a tenth region adjacent to the first region and located between the third region and the first region,
wherein the tenth region extends along the first region, and
wherein, in the tenth region, only the plurality of first power supply terminals among the plurality of external terminals are arranged so as to be adjacent to each other.

14. An electronic device comprising:
a wiring substrate including a third surface and a fourth surface opposite to the third surface; and
a semiconductor device mounted on the third surface of the wiring substrate,
wherein the semiconductor device comprises:
a semiconductor chip having a plurality of circuits including a first circuit;
an interposer substrate including a first surface on which the semiconductor chip is mounted, and a second surface opposite to the first surface and being rectangular in shape when viewed from above; and
a plurality of external terminals arranged in alignment on the second surface of the interposer substrate,
wherein the plurality of external terminals include a plurality of first power supply terminals capable of supplying a first power supply potential to the first circuit,
wherein the second surface includes a terminal arrangement region in which the plurality of external terminals are arranged, and a peripheral region surrounding a periphery of the terminal arrangement region,
wherein the terminal arrangement region includes a first region closest to a first edge of the interposer substrate and extending along the first edge,
wherein, in the first region, only the plurality of first power supply terminals among the plurality of external terminals are arranged so as to be adjacent to each other, and
wherein power consumption of the first circuit is the largest among the power consumption of each of the plurality of circuits of the semiconductor chip.

15. The electronic device according to claim 14,
wherein the plurality of circuits of the semiconductor chip further include a second circuit,
wherein the plurality of external terminals further include a plurality of second power supply terminals capable of supplying a second power supply potential supplied to the second circuit,
wherein the terminal arrangement region includes a second region farther from the first region when viewed from the first edge, and
wherein the plurality of second power supply terminals are arranged in the second region.

16. The electronic device according to claim 15,
wherein the wiring substrate includes:
a plurality of wiring layers stacked in a thickness direction of the wiring substrate; and
a plurality of through-hole wirings formed so as to penetrate the plurality of wiring layers,
wherein, among the plurality of wiring layers, a first wiring layer formed at a position closest to the first surface includes a first power plane which is a conductor pattern electrically connected to the plurality of first power supply terminals,
wherein the plurality of through-hole wirings include:
a first through-hole wiring arranged at a position overlapping the first power plane and being electrically isolated from the first power plane; and
a second through-hole wiring arranged at a position overlapping the semiconductor device,
wherein the number of first through-hole wirings is fewer than the number of second through-hole wirings.
